(19) United States
(12) Patent Application Publication
(10) Pub. No.: US 2011/0265855 A1
(43) Pub. Date: Nov. 3, 2011

(54) SOLAR RADIATION PRISMATIC CONCENTRATOR

(75) Inventors: Itay Baruchi, Tel Aviv (IL); Gonen Fink, Tel Aviv (IL)

(73) Assignee: PYTHAGORAS SOLAR INC., Wilmington, DE (US)

(21) Appl. No.: 13/142,766

(22) PCT Filed: Dec. 31, 2009
(86) PCT No.: PCT/IL2009/001234

§ 371 Date: Jun. 29, 2011

Related U.S. Application Data
(60) Provisional application No. 61/193,868, filed on Dec. 31, 2008.

(51) Int. Cl. H01L 31/052; H01L 31/0232

(52) U.S. Cl. 136/246; 136/259

(57) ABSTRACT

A solar radiation collector is provided. The collector is configured to receive solar radiation from a range of angles including a first range constituting an acceptance angle, and a second range constituting angles outside said first range. It further includes a photovoltaic cell and a regulator, which is configured to regulate the appearance of the collector to an observer within the second range, constituting a source of visible radiation which is visible to an observer within the second range.

### FIELD OF THE INVENTION

This invention relates to solar radiation collectors, and especially to those which are configured to concentrate the radiation.

### BACKGROUND OF THE INVENTION

It is well known that solar radiation can be utilized by various methods to produce useable energy. One method involves the use of a photovoltaic cell, which is configured to convert solar radiation to electricity. Solar radiation collectors are typically used to gather sunlight or other radiation and direct it toward a photovoltaic cell. Often, concentrators are provided in order to focus the radiation from an area to a photovoltaic cell which is significantly smaller than the area.

Typically, the color of a photovoltaic cell is dark blue or black, resulting in a similarly colored collector. Consequently, when such a collector is mounted on a building, it is noticeable, especially when the area of the building to which it is mounted is of a contrasting color.

### SUMMARY OF THE INVENTION

According to one aspect of the present invention, there is provided a solar radiation collector configured to receive solar radiation from a range of angles including a first range constituting an acceptance angle, and a second range constituting angles outside said first range, the collector comprising a photovoltaic cell and a regulator, which is configured to regulate the appearance of the collector to an observer within the second range, constituting a source of visible radiation which is visible to an observer within the second range.

According to another aspect of the present invention, there is provided a solar radiation collector comprising:
a prismatic concentrator having an entrance aperture configured for receiving radiation from a range of angles including a first range constituting the acceptance angle of the concentrator, and a second range constituting angles outside the first range;
a photovoltaic cell co-disposed with the concentrator such that it is reached by radiation impinging upon the entrance aperture within the first range; and
a regulator constituting a source of visible radiation of a predetermined color, i.e., from which such radiation emanates, and being co-disposed with the concentrator such that it is visible to an observer within the second range (i.e., it lies along an optical path which is followed by radiation impinging upon the entrance aperture in the second range; thus, at least a portion of radiation emanating from the regulator will reach the entrance aperture at an angle such that it is rejected within the second range). In addition, the regulator may be reached by radiation impinging upon the entrance aperture within the second range.

The concentrator may have a triangular cross-section, with a first side thereof constituting a receiver plane, a second side thereof constituting the entrance aperture, and a third side constituting a bottom reflecting surface; the regulator being formed equivalently to the concentrator, and being co-disposed therewith such that the respective second side of each of the concentrator and the regulator are parallel to one another, and the respective third side of each of the concentrator and the regulator are parallel to and face one another. The angle between the second and third sides of the concentrator may be equal to the angle of total internal reflection of the concentrator.

A solar radiation collector according to the above allows an observer outside the acceptance angle to see radiation from the regulator. Thus, the color of the collector, at least for observers outside the acceptance angle, is at least partially determined by the regulator.

It will be appreciated that herein the specification and claims, the term “source” is to be understood according to its broadest definition, including, but not limited to, converting one type of energy into visible radiation (e.g., by using radiation emitting sources such as LEDs to convert electrical energy into visible radiation), reflecting radiation incident thereon within a range of wavelengths such that the reflected radiation is of a predetermined color which is different from the impinging radiation (i.e., only a portion of the wavelengths are reflected), conversion of radiation of a first frequency into radiation of a second frequency, e.g., by luminescence (being referred to as a source of radiation of the second wavelength), redirecting incident radiation from an external source at a desired angle, etc. It will be further appreciates that the term “emanating” is to be understood as describing radiation which comes from such a source.

The regulator may be located in a position which does not obstruct radiation impinging upon the entrance aperture within the first rage from reaching the photovoltaic cell.

The regulator may be configured to change the apparent color of the radiation, e.g., by reflecting certain range of wavelengths of the visible spectrum of the radiation reaching it, causing the reflected radiation to have different color from that of the impinging light (which is typically white light). In particular, this may be accomplished by absorbing predetermined wavelengths of the impinging light, thus imparting the predetermined color to the reflected light.

The regulator may comprise a light emitter, such as one or more LEDs, configured to emit light of the predetermined color. For example, the light emitter may comprise three LEDs, one each being configured to emit red, blue, and green light. A controller may be further provided to control the operation of each of the LEDs.

The concentrator may further comprise a bottom reflecting surface configured to reflect at least some of the radiation from the first range by total internal reflection, with the collector further comprising a mirrored surface co-disposed with the bottom reflecting surface so as to reflect radiation passing therethrough toward the regulator.

The entrance aperture may meet the bottom reflecting surface at a first end thereof, with the mirrored surface meeting the bottom reflecting surface at a second end thereof, the regulator being located near or at the first end of the bottom reflecting surface.

The bottom reflecting surface may comprise two faces disposed at an angle to one another. For example, the mirrored surface may be disposed parallely to a first of the faces and be separated therefrom by a small gap. The mirrored surface may furthermore project beyond the first face, the projecting portion being angled with respect to a second of the faces, with the regulator spanning between the second face and the mirrored surface.

Alternatively, the regulator may be disposed parallely to a second of the faces and be separated therefrom by a small gap.

The concentrator may comprise a bottom reflecting surface configured to reflect at least a portion of the radiation from the first range by total internal reflection towards the photovoltaic cell, the collector further comprising a dual-purpose surface disposed below the bottom reflecting surface and being formed with a saw-tooth cross-section having a plurality of teeth, each tooth having forward and rearward facing surfaces, each of the surfaces being alternately formed as either a mirrored surface or as a portion of the regulator. The mirrored surfaces of the saw-tooth structure are disposed so as to reflect light from the first range, which was not reflected by total internal reflection, towards the said photovoltaic cell.

The mirrored surfaces may constitute the forward facing surfaces, with the portions of the regulator constitute the rearward facing surfaces. Alternatively, the mirrored surfaces may constitute the rearward facing surfaces, with the portions of the regulator constitute the forward facing surfaces.

The concentrator may comprise a bottom surface being formed with a saw-tooth cross-section having a plurality of teeth, each tooth having forward and rearward facing surfaces, each of the surfaces being alternately formed as either a reflecting surface or provided with a portion of the regulator, each of the reflecting surfaces being configured to reflect radiation from the first range by total internal reflection, or to refract it by a bottom mirror.

The reflecting surfaces may constitute the forward facing surfaces, with the rearward facing surfaces being provided with the portions of the regulator. Alternatively, the reflecting surfaces may constitute the rearward facing surfaces, with the forward facing surfaces being provided with the portions of the regulator. A mirrored surface may be disposed below the bottom reflecting surface.

The concentrator may comprise a bottom reflecting surface configured to reflect radiation from the first range by total internal reflection, the regulator being disposed parallely to and substantially along the entire length of the bottom reflecting surface and separated therefrom by a small gap. The concentrator may have a triangular cross-section, with a first side thereof constituting a receiver plane, a second side thereof constituting the entrance aperture, and a third side constituting the bottom reflecting surface, the angle between the second and third sides being equal to the angle of total internal reflection of the concentrator. The regulator may be formed equivalently to the concentrator, and be co-disposed therewith such that the respective second side of each of the concentrator and the regulator are parallel to one another, and the respective third side of each of the concentrator and the regulator are parallel to and face one another. The third sides may be separated from each other by a small gap.

The concentrator may comprise sidewalls, the regulator being located adjacent at least one of the sidewalls. For example, the regulator may be disposed parallely to the at least one sidewall and separated therefrom by a small gap.

The concentrator comprises a dielectric filled compound parabolic concentrator (CPC), the regulator being disposed adjacent at least a portion of sidewalls of the CPC. The regulator may be disposed parallely to the sidewalls and separated therefrom by a small gap.

### BRIEF DESCRIPTION OF THE DRAWINGS

In order to understand the invention and to see how it may be carried out in practice, embodiments will now be described, by way of non-limiting examples, with reference to the accompanying drawings, in which:

FIG. 1 is a cross-sectional view of a typical solar radiation collector which may be used with the present invention;

FIGS. 2A and 2B are cross-sectional views of the collector illustrated in FIG. 1, according to two embodiments of the present invention;

FIGS. 3A through 3C are modifications of the embodiments illustrated in FIGS. 2A and 2B;

FIG. 4A is a cross-sectional view of an embodiment being another modification of the embodiments illustrated in FIGS. 2A and 2B;

FIG. 4B is a close-up view of an area of FIG. 4A;

FIG. 4C is a modification of the embodiment illustrated in FIG. 4A;

FIG. 5 is a perspective view of a further embodiment of a collector according to the present invention;

FIG. 6 is a perspective view of an example of a regulator according to the present invention;

FIG. 7 is a plan view of a portion of an array of collectors;

FIGS. 8A and 8B are cross-sectional views of further embodiments of collectors according to the present invention;

FIGS. 9A and 9B illustrate partially transparent collectors according to embodiments of the present invention; and

FIG. 10 illustrates a solar collection unit, comprising an array of solar radiation collectors according to any of FIGS. 2A through 9B, in use according to one example of the present invention.

### DETAILED DESCRIPTION OF EMBODIMENTS

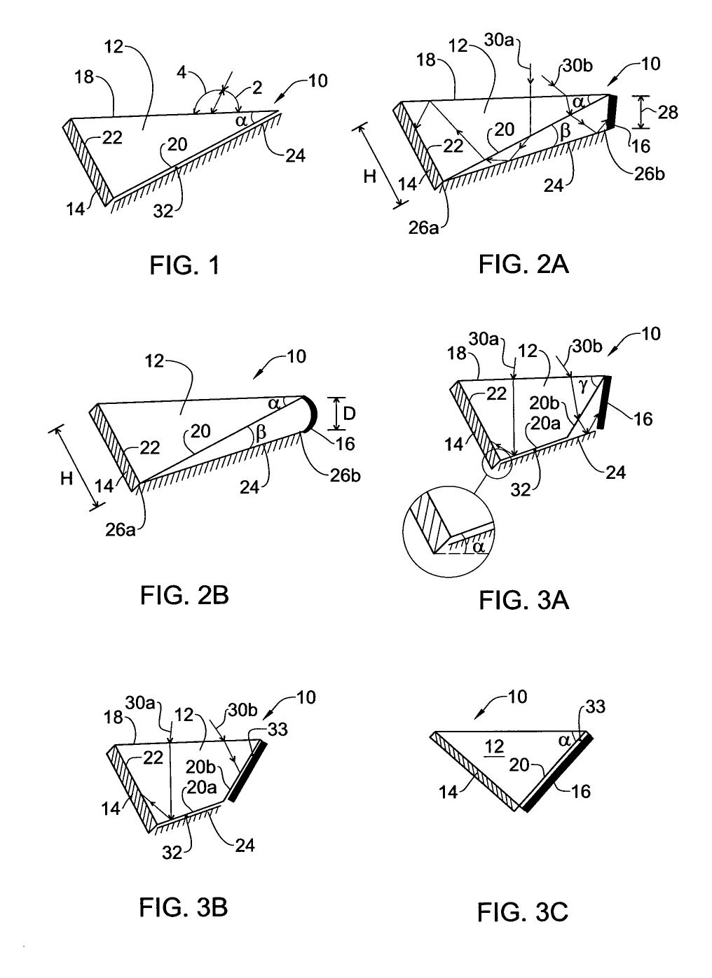

As illustrated in FIG. 1, there is provided a solar radiation collector, which is generally indicated at 10, which is typical of the type which may be configured for use with the present invention. The collector 10 comprises a prismatic concentrator 12, a photovoltaic cell 14, and an optional mirrored surface 24 which may be separated from the concentrator by a small gap 32. It will be appreciated that each of the elements of the collector 10 may comprises one or more portions without deviating from the scope of the present invention, mutatis mutandis.

The concentrator 12 may be any known concentrator, such as that disclosed in WO 2008/072224 to the present applicant, which is incorporated herein by reference. It may be made from Poly(methyl methacrylate) (PMMA), or any other appropriate material having an index of refraction n greater than 1, and more particularly greater than 1.5. According to one example, the concentrator comprises an entrance aperture 18 at a front side thereof (hereafter in the specification and claims, the term “front” is to be understood as referring to the side of the concentrator, entrance aperture, and/or collector from which incident solar radiation impinges, i.e., toward the side of the entrance aperture which faces away from the concentrator 12; conversely, the term “behind” is to be understood as referring to the side of the concentrator, entrance aperture, and/or collector which is opposite that from which incident solar radiation impinges) configured for being impinged upon by incident radiation, a bottom reflecting surface 20, optionally co-disposed with the mirrored surface 24, together configured to reflect radiation impinging thereon from within the prism back into the prism, and a receiver plane 22, to which the photovoltaic cell 14, or another concentrator or portion of the concentrator, is attached or formed integrally therewith, for example as described in WO 2008/072224 (the receiver plane is designed such that all radiation which reaches it eventually reaches the photovoltaic cell). The concentrator may be formed as a right triangle as illustrated, and have an edge angle α. The geometrical concentration C_{g} of such a concentrator can be expressed as:

$${C}_{g} = \frac{1}{sin ( α )} .$$

The concentrator 12 has an associated acceptance angle (i.e., an angle with respect to the entrance aperture 18). The acceptance angle is related to the edge angle α.

Incident radiation impinging upon the entrance aperture 18 within the range of the acceptance angle, indicated at 2, enters the prism and is directed toward the receiver plane 22, e.g., reflected within the prism via total internal reflection from the bottom reflecting surface 20 or from the mirrored surface 24, and thus reaches the photovoltaic cell. It will be appreciated that the term “directed towards”, as used herein the specification and claims, includes reflecting at an angle directly toward, or reflecting at an angle which eventually leads toward, e.g., toward the interior surface of the entrance aperture 18, from which the radiation is further reflected toward the receiver plane 22 or again toward the bottom reflecting surface 20 (for example reflecting between the bottom reflecting surface and the entrance aperture multiple times until it reaches the receiver plane). Incident radiation impinging upon the entrance aperture 18 outside the range of the acceptance angle, indicated at 4, (i.e., at angles outside the acceptance angle) enters the concentrator 12, reflects towards the internal side of the aperture entrance 18, and exit through it. For α>=θ_{c}, all radiation impinging the entrance aperture 18 within the acceptance angle 2 is reflected via total internal reflection towards the receiver plane 22 and thus the mirror surface 24 is not required.

The regulator constitutes a source of visible radiation of a predetermined color. This may be realized, for example, by providing a material which reflects only a range of wavelengths within the spectrum of the incident radiation, so that the color of reflected radiation is different from that of the incident radiation. Optionally, this may be accomplished by providing a material which is luminescent or phosphorescent, so that it emits a certain spectrum upon the incidence of radiation (or for a duration after exposure to radiation). Alternatively, a radiation emitting source, such as one or more LEDs (light emitting diodes), as described below may be provided as a regulator. The color associated with the regulator determines the color of the collector 10 (i.e., the color which is visible to an observer outside the range of the acceptance angle of the concentrator 12).

According to one example, as illustrated in FIGS. 2A and 2B, a mirrored surface 24 is provided below the bottom reflecting surface 20. The mirrored surface is angled with respect to the bottom reflecting surface 20, such that is substantially meets the intersection of the receiver plane 22 and the bottom reflecting surface 20 at a first end 26a thereof, and is separated by a distance 28 at a second end thereof 26b. The collector may be designed such that the angle β formed between the bottom reflecting surface 20 and the mirrored surface 24 is determined as per the following:

$$β = \frac{{sin}^{- 1} ( \frac{n}{{n}_{0}} sin α ) - {sin}^{- 1} [ \frac{n}{{n}_{0}} sin ( {θ}_{c} - α ) ]}{2} ,$$

where n is the refractive index of the material of the prismatic concentrator 12, n₀, which is less than n, is the refractive index of the material between the bottom reflecting surface 20 and the mirrored surface 24 (usually air with n₀=1), and θ_{c} is the critical angle for total internal reflection. Thus, the angle β is designed to allow for radiation which reaches the collector 10 within the acceptance angle to reach the photovoltaic cell 14, and at least a portion of the radiation which reaches the collector outside the acceptance angle to reach the regulator. The distance D between the entrance aperture 18 and the mirrored surface 24 can be expressed as:

$$D = \frac{H sin β}{tan α cos ( α - β )} ,$$

where H is the height of the receiver plane 22, for example as indicated in FIGS. 2A and 2B. The regulator 16 is located adjacent the second end 26b of the bottom reflecting surface 20, e.g., spanning between the bottom reflecting surface and the mirrored surface. As illustrated in FIG. 2A, the regulator 16 may be straight, or, as illustrated in FIG. 2B, it may be curved. It will be appreciated that FIGS. 2A and 2B illustrated two non-limiting examples of the shape of the regulator 16, and it may be provided as any desired shape with deviating from the scope of the present invention mutatis mutandis. The regulator may be a colored surface configured to reflect the incident radiation diffusively or a specular interference mirror.

During use, incident radiation impinging upon the entrance aperture 18 within the range of the acceptance angle enters the concentrator 12, and at least some of it is reflected from the bottom reflecting surface 20 via total internal reflection toward the receiver plane 22. Some of the radiation within the acceptance angle may leave the concentrator via the bottom reflecting surface, reflect from the mirror 24, and re-enter the concentrator via the surface 20 towards the receiver plane 22, for example along a representative path indicated in FIG. 2A at 30a. Incident radiation impinging upon the entrance aperture 18 outside the range of the acceptance angle enters the concentrator 12, and leaves via the bottom reflecting surface 20. The radiation is then reflected off of the mirrored surface 24 and the outside surface of the bottom reflecting surface 20 until it reaches the regulator 16. A representative path that such radiation may take is indicated in FIG. 2A at 30b. Once the radiation reaches the regulator 16, its spectrum and color change after reflection, and part of the reflected and/or diffusive radiation follows paths that eventually exit the entrance aperture 18 (in a case where the regulator is configured to diffuse incident radiation, most of the radiation will follow non-specular paths, some of which may reach the photovoltaic cell). Such radiation will, to an outside observer, appear to be the predetermined color. Thus, the concentrator 10 is designed and/or configured to utilize radiation which would not, in any event, reach the photovoltaic cell 14 and reflect it at a predetermined color.

A modification of the example illustrated in FIGS. 2A and 2B is illustrated in FIG. 3A. The concentrator 12 according to the example illustrated therein comprises a bottom reflecting surface having first and second faces 20a, 20b which are disposed at an angle to one another, such that the bottom reflecting surface appears in cross-section to be bent. The first and the second faces 20a and 20b are angled with respect to entrance aperture plane 18 at angles α and γ respectively (the angle α being defined between the extension of the planes of 20a and of 18, which is illustrated in FIG. 3A as the angle between the first face and a line which is parallel to the entrance aperture; the angle γ being defined between the entrance aperture 18 and the second face 20b). The mirrored surface 24 is disposed so that it is parallel and adjacent to the first face 20a, and optionally separated therefrom by a small gap 32 (it will be appreciated that whenever two surfaces are separated by a small gap, they may be mechanically attached to one another only at edges thereof), and, due to the angle of the bottom reflecting surface, is angled with respect to the second face 20b.

During use, some of the incident radiation impinging upon the entrance aperture 18 within the range of the acceptance angle enters the concentrator 12, and is reflected off of the first face 20a therewithin, for example along a representative path indicated at 30a toward the receiver plane 22. It will be appreciated that, while not indicated in FIG. 3A, some of the radiation within the range of the acceptance angle will be totally internally reflected off of the second face 20b toward the receiver place 22, and some will be refracted by it and reflected by the mirror 24 back into the prism and towards the receiver plane 22. Some of the incident radiation impinging upon the entrance aperture 18 outside the range of the acceptance angle enters the concentrator 12, and leaves via the second face 20b. The radiation may then be reflected off of the mirrored surface 24 and the outside surface of the bottom second face 20b until it reaches the regulator 16. A representative path that such radiation may take is indicated at 30b. Once the radiation reaches the regulator 16, its spectrum and color change after reflection, and part of the reflected and/or diffusive radiation follows paths that finally exits the entrance aperture 18 (some of the radiation will follow different paths that may reach the photovoltaic cell). Such radiation will, to an outside observer, appear to be the predetermined color.

Another modification of the example illustrated in FIGS. 2A and 2B is illustrated in FIG. 3B. This modification is similar to that illustrated in FIG. 3A, with the exception that γ=θ_{c} and the regulator 16 is angled such that it is disposed parallel to the second face 20b, and optionally separated therefrom by a small gap 33. The planes of 20a and 20b are angled at angles α and θ_{c} respectively in a similar manner to the case illustrated in FIG. 3A.

During use, some of the incident radiation impinging upon the entrance aperture 18 within the range of the acceptance angle enters the concentrator 12, and is reflected off of the first face 20a therewithin, for example along a representative path indicated at 30a toward the receiver plane 22. It will be appreciated that, while not indicated in FIG. 3A, some of the radiation within the range of the acceptance angle will be totally internally reflected off of the second face 20b toward the receiver place 22. Some of the incident radiation impinging upon the entrance aperture 18 outside the range of the acceptance angle enters the concentrator 12, and leaves via the second face 20b. The radiation then impinges upon the regulator 16. A representative path that such radiation may take is indicated at 30b. Once the radiation reaches the regulator 16, its spectrum and color change after reflection, and part of the reflected and/or diffusive radiation follows paths that eventually exit the entrance aperture 18 (some of the diffused radiation may reach the photovoltaic cell). Such radiation will, to an outside observer, appear to be the predetermined color. If the angle γ between the surface 20b and 18 is smaller than the critical angle, the ranges of incidence angles that will end at the receiver plane differ for light impinging on different parts of the entrance aperture. In this case, the acceptance angle is defined to encompass all different incidence angles that end at the receiver plane.

Each of the modifications illustrated in FIGS. 3A and 3B allow for a lager regulator 16, but the overall concentration of the collector 10 may be reduced.

As illustrated in FIG. 3C, the concentrator 12 may be provided as having an edge angle α equal to the angle of total internal reflection. Thus, the regulator 16 may be provided below the entire length of the bottom reflecting surface 20, with a gap 33 being optionally provided therebetween to permit total internal reflection of radiation rays entering the concentrator 12 within the acceptance angle.

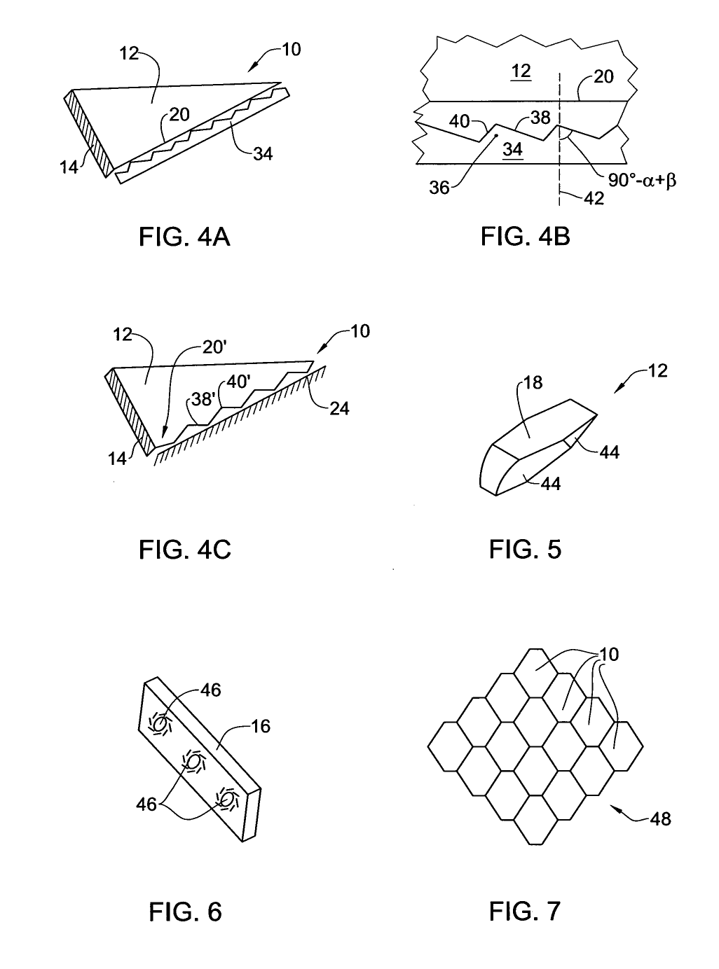

Another modification of the example illustrated in FIGS. 2A and 2B is illustrated in FIGS. 4A and 4B, in which a dual-purpose surface 34 having a saw-tooth cross-section is provided below the bottom reflecting surface 20. Each tooth 36 thereof has a forward facing surface 38, which may be formed as a mirrored surface, and a rearward facing surface 40, which may constitute the regulator. Each tooth 36 is designed so that a line 42 perpendicular to the bottom reflecting surface 20 and intersecting the intersection between the forward and rearward facing surfaces 38, 40 forms an angle with the forward facing surface equal which can be expressed as 90°−α+β (α and β each as calculated above), as illustrated in FIG. 4B. The concentrator edge angle α is smaller than the critical angle, in particular about half the critical angle or slightly smaller than it.

Alternatively, as illustrated in FIG. 4C, the bottom reflecting surface may be replaced with a surface 20′ having a saw-tooth cross-section, having forward facing surfaces 38′ and rearward facing surfaces 40′ thereof being provided with regulators 16, and a mirrored surface 24 provided therebelow to reflect incident radiation.

As illustrated in FIG. 5, the concentrator 12 may be formed having sidewalls 44, e.g., extending parallely downwardly from the entrance aperture 18. Some or all of these sidewalls 44 may be provided with regulators 16 adjacent thereto.

As described above, and as illustrated in FIG. 6, the regulator 16 may include one or more LEDs 46. If one LED 46 is provided, then the color of the collector 10 is the color of the LED (assuming that the concentrator 12 itself is clear, otherwise it is the color of the LED as viewed through the color of the concentrator). If three LEDs 46 are provided, for example, one each being red, blue, and green, then any desired color may be produced by varying the intensity of output of each of the LEDs. For this purpose, a controller (not illustrated) may be provided for each regulator 16 to determine the color of its respective collector 10 (either one controller per collector, or one controller controlling many collectors). When a plurality of identical collectors 10 are arranged such that the entrance apertures 12 thereof form a tessellated array 48 (as illustrated in FIG. 7), the controllers may be used so that a moving image is visible to an observer outside the range of the acceptance angle.

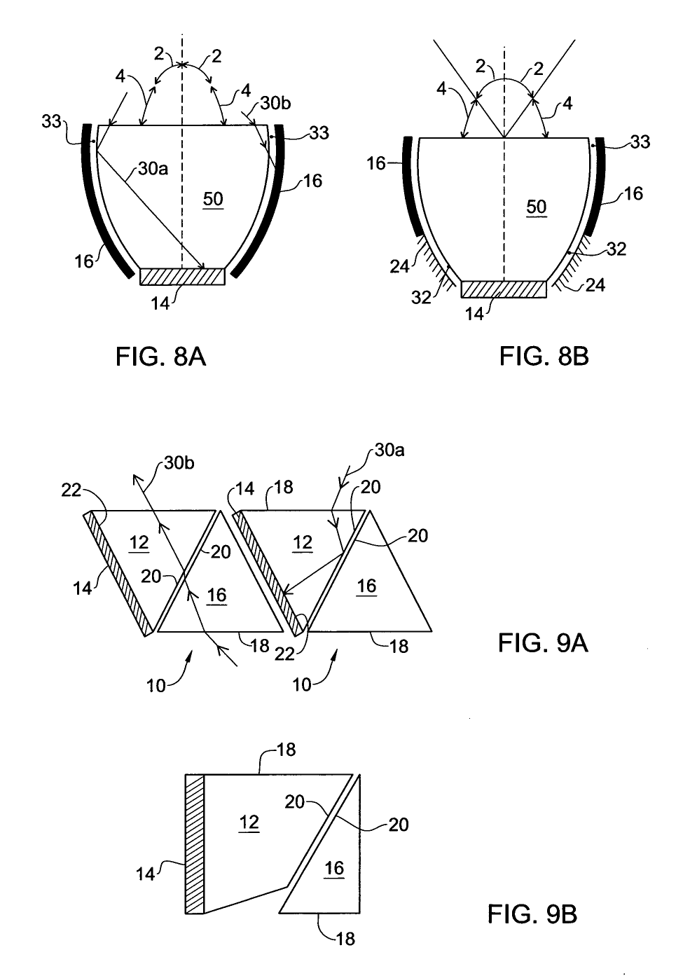

As illustrated in FIGS. 8A and 8B, regulators 16 may be provided for dielectric-filled compound parabolic concentrators (CPCs) 50. As illustrated in FIG. 8A, the regulators 16 may be provided along the entire side of the CPC 50, with a gap 33 provided therebetween, or a portion of the side may be provided with a mirrored surface 24, with a gap 32 optionally provided therebetween, as illustrated in FIG. 8B. radiation impinging the concentrator within the acceptance angle will be reflected via total internal reflection towards the receiver, whereas radiation impinging outside the acceptance angle will exit the concentrator side surface and reach the regulator. It will than be diffused and portion of it reflected back along a path which eventually exit the concentrator entrance aperture.

As illustrated in FIG. 9A, a concentrator 12 designed as per that described with reference to and illustrated in FIG. 3C may be used to provide a collector 10 which is transparent to an observer outside the range of the acceptance angle. This may be accomplished by providing a regulator 16 which is designed equivalent to the concentrator 12, and positioning it so that the bottom reflecting surfaces 20 of each are parallel to one another and separated by a small gap 33, and the entrance apertures 18 of each are parallel to one another. As will be seen below, in this case, the “color” is the radiation which is behind the collector 10 and the regulator 16 serves to bend the radiation before reaching the concentrator 12. In this way, it constitutes a “source” of radiation.

During use, incident radiation impinging upon the entrance aperture 18 within the range of the acceptance angle enters the concentrator 12, and is reflected therewithin, for example along a representative path indicated at 30a toward the receiver plane 22 from the bottom reflecting surface 20 by total internal reflection. Incident radiation impinging upon the entrance aperture 18 outside the range of the acceptance angle enters the concentrator 12, and leaves via the bottom reflecting surface 20. The radiation is then enters the regulator 16 through the surface 20 thereof, and exits through surface 18. Due to symmetry, the angle at which such radiation leaves the regulator 16 is equal to the angle at which it enters the concentrator 12. A representative path that such radiation may take is indicated at 30b. (For the sake of simplicity only, two adjacent collectors 10 are illustrated in FIG. 9A, each having one of paths 30a and 30b.) Thus, for an observer outside the range of the acceptance angle, the collector 10 appears transparent. (It will be appreciated that the collector 10 appears transparent to observers on either side thereof, provided that they are outside the range of the acceptance angle.) This can be useful, for example as a window in which it is only important to provide viewing therethrough from a range of angles.

As illustrated in FIG. 9B, the collector 10 may be provided with a regulator 16 which is not designed to be equivalent to the concentrator 12.

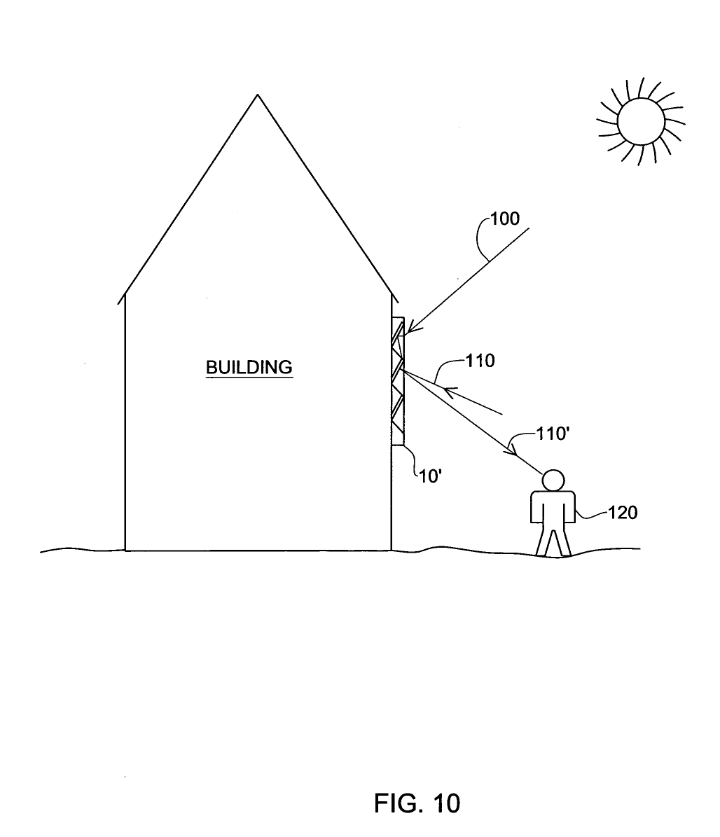

FIG. 10 illustrates how a solar collector according to the present invention may be used. A solar collection unit 10′, which typically comprises an array of collectors 10, may be mounted vertically on a building or other structure. Incident radiation 100 which impinges upon the unit 10′ within the acceptance angle is reflected, as described above with reference to each example, toward the photovoltaic cell of each collector 10. Radiation, such as diffuse light, which impinges upon the unit 10′ outside the acceptance angle reaches the regulator of each collector 10, and is reflected outwardly of the collectors toward an observer who is outside the acceptance angle of the collectors. Thus, the unit uses incident radiation within the acceptance angle to generate electricity, and incident radiation outside the acceptance angle to impart a predetermined color to the unit.

It will be appreciated that when using such an array of collectors, each collector can be imparted with a suitable color, i.e., by using appropriate regulators, to present an image to the observer. Such an image can be useful as an informational sign, advertisement banner, etc. In addition, when the regulator comprises LEDs, for example as described with reference to FIG. 6 above, the panel may be also used to present a moving image, or to change a still image when desired.

Those skilled in the art to which this invention pertains will readily appreciate that numerous changes, variations and modifications can be made without departing from the scope of the invention mutatis mutandis.

1.-34. (canceled)

35. A solar radiation collector, comprising:
a prismatic concentrator having an entrance aperture configured for receiving radiation from a range of angles including a first range constituting the acceptance angle of the concentrator, and a second range constituting angles outside said first range;
a photovoltaic cell co-disposed with said concentrator such that it is reached by radiation impinging upon said entrance aperture within the first range; and
a regulator constituting a source of visible radiation of a predetermined color and being co-disposed with said concentrator such that it is visible to an observer within the second range.

36. The solar radiation collector according to claim 35, wherein said regulator is located in a position which does not obstruct radiation impinging upon the entrance aperture within the first range from reaching the photovoltaic cell.

37. The solar radiation collector according to claim 35, wherein said regulator is configured to reflect radiation in at least one color which is different from that of the radiation impinging upon it.

38. The solar radiation collected according to claim 37, wherein said regulator comprises at least one radiation emitting source configured to emit radiation of said at least one color.

39. The solar radiation collector according to claim 38, further comprising a controller configured to control the operation of each of said at least one radiation emitting source.

40. The solar radiation collector according to claim 35, said concentrator further comprising a bottom reflecting surface configured to reflect radiation from said first range by total internal reflection, said collector further comprising a mirrored surface co-disposed with said bottom reflecting surface so as to reflect radiation, impinging upon the concentrator within the first range and passing through the bottom reflecting surface, toward the photovoltaic cell, and to reflect radiation, impinging upon the concentrator within the second range and passing therethrough, toward said regulator.

41. The solar radiation collector according to claim 40, wherein said entrance aperture meets said bottom reflecting surface at a first end thereof, said mirrored surface meeting said bottom reflecting surface at a second end thereof, said regulator being located near or at said first end of the bottom reflecting surface.

42. The solar radiation collector according to claim 35, said concentrator further comprising a bottom reflecting surface configured to reflect radiation from said first range by total internal reflection, said regulator being disposed parallely to and substantially along the entire length of said bottom reflecting surface.

43. The solar radiation collector according to claim 42, said concentrator having a triangular cross-section, with a first side thereof constituting a receiver plane, a second side thereof constituting said entrance aperture, and a third side constituting said bottom reflecting surface, the angle between said second and third sides being related to the acceptance angle.

44. The solar radiation collector according to claim 43, wherein said regulator is formed equivalently to said concentrator, and is co-disposed therewith such that the respective second side of each of said concentrator and said regulator are parallel to one another, and the respective third side of each of the concentrator and said regulator are parallel to and face one another.

45. The solar radiation collector according to claim 44, wherein said third sides are separated by a small gap.

46. The solar radiation collector according to claim 35, said concentrator comprising sidewalls, said regulator being located adjacent at least one of said sidewalls.

47. The solar radiation collector according to claim 46, wherein said regulator is disposed parallely to said at least one sidewall.

48. The solar radiation collector according to claim 35, wherein said concentrator comprises a dielectric filled compound parabolic concentrator (CPC), said regulator being disposed adjacent at least a portion of sidewalls of said CPC.

49. The solar radiation collector according to claim 47, wherein said regulator is disposed parallely to said sidewalls and separated therefrom by a small gap.

50. An array of solar radiation collectors, each of said collectors being formed in accordance with claim 35.

51. The array according to claim 50, wherein said collectors are arranged such that their predetermined colors combine to form an image.

52. The array according to claim 51, wherein said image is a moving image.
